(19) United States
(12) Patent Application Publication
(10) Pub. No.: US 2026/0090447 A1
(43) Pub. Date: Mar. 26, 2026

(54) SEMICONDUCTOR DEVICE AND ASSOCIATED METHOD IN A FAN-OUT WAFER LEVEL CHIP SCALE PACKAGE

(71) Applicant: STMicroelectronics International N.V., Geneva (CH)

(72) Inventor: Loic Pierre Louis RENARD, Singapore (SG)

(21) Appl. No.: 19/323,568

(22) Filed: Sep. 9, 2025

Related U.S. Application Data
(60) Provisional application No. 63/697,687, filed on Sep. 23, 2024.

(51) Int. Cl. H01L 23/00; H01L 21/56

(52) U.S. Cl. CPC H10W 74/014; H10W 70/09; H10W 70/60; H10W 70/6528; H10W 72/0198

(57) ABSTRACT

In accordance with various embodiments of the present disclosure, a fan-out wafer-level chip scale package is provided that comprises a semiconductor die having a top side with an active layer, an opposing bottom side, and four peripheral sides; a molding compound surrounding the peripheral sides of the semiconductor die; a redistribution layer at least partially embedded in a dielectric layer and providing a plurality of electrical connections to the semiconductor die; a plurality of solder balls on the redistribution layer, each of the plurality of solder balls providing an electrical connection to a corresponding connection point of the semiconductor die; and a first conductive wall embedded in the molding compound adjacent and substantially parallel to a first one of the peripheral sides of the semiconductor die, the first conductive wall having a top edge in electrical contact with the redistribution layer.

### CROSS-REFERENCE TO RELATED APPLICATIONS

This application claims priority to and the benefit of US Provisional Patent Application Serial No. 63/697,687, filed September 23, 2024, and titled “SEMICONDUCTOR DEVICE AND ASSOCIATED METHOD IN A FAN-OUT WAFER LEVEL CHIP SCALE PACKAGE,” which is incorporated herein by reference in its entirety.

### FIELD OF THE INVENTION

Example embodiments of the present disclosure relate generally to semiconductor devices and, in particular, to wafer-level chip scale packaging (WLCSP).

### BACKGROUND

Wafer-level chip scale packaging (WLCSP) is the smallest package currently available on the market, which comprises a bare die with a redistribution layer (RDL) to rearrange the pins or contacts on the die into a ball grid array.

There are two kinds of wafer level packaging: fan-in and fan-out. Fan-in WLCSP (FI-WLCSP) packages have an RDL that is the same size as that of the die, whereas fan-out WLCSP (FO-WLCSP) packages have an RDL that is larger than the die. The RDL is often made out of a dielectric with copper plated connections on its surface. FO-WLCSP packages are typically used in cases where fan-in packages are not able to provide enough connections.

FO-WLCSP technology is an enhancement of standard wafer-level packages developed to provide a solution for semiconductor devices requiring a higher integration level and a greater number of external contacts. It provides a smaller package footprint with higher input/output (I/O) along with improved thermal and electrical performance.

FO-WLCSP takes individual dies and embeds them in a low-cost material such as epoxy mold compound (EMC) with space allocated between each die for additional I/O connection points. The RDLs are formed using PVD seed deposition and subsequent electroplating/patterning to re-route I/O connections on the die to the mold compound regions in the periphery. The assembly is then singulated to create individual FO-WLCSP devices.

Applicant has identified many technical challenges and difficulties associated with FO-WLCSP technology. Through applied effort, ingenuity, and innovation, Applicant has solved problems related FO-WLCSP technology by developing solutions embodied in the present disclosure, which are described in detail below.

### BRIEF SUMMARY

Various embodiments described herein related to FO-WLCSP devices, and methods for manufacturing FO-WLCSP devices.

In accordance with various embodiments of the present disclosure, a method of manufacturing a semiconductor device comprises constructing an assembly and singulating the assembly into a plurality of fan-out wafer-level chip scale packages (FO-WLCSP). Constructing the assembly comprises: (a) disposing a leadframe on a temporary substrate, the leadframe comprising at least a plurality of substantially parallel conductive walls; (b) disposing a plurality of semiconductor dies on the temporary substrate, each of the plurality of semiconductor dies disposed with its active layer against the temporary substrate, the plurality of semiconductor dies comprising a plurality of subgroups of semiconductor dies, each subgroup of semiconductor dies is disposed on the temporary substrate such that a same side of each of the plurality of semiconductor dies in each subgroup of semiconductor dies is adjacent a corresponding one of the plurality of substantially parallel conductive walls; (c) enclosing the leadframe and the plurality of semiconductor dies in a molding compound; (d) removing the temporary substrate; (e) disposing a plurality of redistribution layers on the active layer of corresponding ones of the plurality of semiconductor dies such that each of the plurality of redistribution layers provides a plurality of electrical connections to a corresponding one of the plurality of semiconductor dies, each of the plurality of redistribution layers at least partially embedded in a dielectric layer; and (f) disposing a plurality of solder balls on each of the plurality of redistribution layers, each of the plurality of solder balls providing an electrical connection to a corresponding connection point of a corresponding one of the plurality of semiconductor dies. Each FO-WLCSP comprises a corresponding one of the plurality of semiconductor dies, a corresponding one of the plurality of redistribution layers, corresponding ones of the plurality of solder balls, and a portion of a corresponding one of the plurality of substantially parallel conductive walls.

In some embodiments, the plurality of substantially parallel conductive walls is a first plurality of substantially parallel conductive walls; the leadframe comprises a second plurality of substantially parallel conductive walls, each wall of the second plurality of substantially parallel conductive walls being substantially perpendicular to the first plurality of substantially parallel conductive walls such that the leadframe forms a substantially rectangular grid; each of the plurality of semiconductor dies is disposed on the temporary substrate such that two adjacent sides of each of the plurality of semiconductor dies are adjacent, respectively, a portion of a corresponding one of the first plurality of substantially parallel conductive walls and a portion of a corresponding one of the second plurality of substantially parallel conductive walls; and the assembly is singulated such that each FO-WLCSP comprises the corresponding portion of the corresponding one of the first plurality of substantially parallel conductive walls and the corresponding portion of the corresponding one of the second plurality of substantially parallel conductive walls.

In some embodiments, each of the first plurality of substantially parallel conductive walls comprises a double wall having a first sub-wall and a second sub-wall substantially parallel to the first sub-wall; and the assembly is singulated such that each FO-WLCSP comprises a portion of a first sub-wall of a corresponding one of the plurality of substantially parallel conductive walls on one side of each semiconductor die and a portion of a second sub-wall of a different corresponding one of the plurality of substantially parallel conductive walls on an opposite side of each semiconductor die.

In some embodiments, the plurality of substantially parallel conductive walls is a first plurality of substantially parallel conductive walls; each of the first plurality of substantially parallel conductive walls comprises a double wall having a first sub-wall and a second sub-wall substantially parallel to the first sub-wall; the leadframe comprises a second plurality of substantially parallel conductive walls, each wall of the second plurality of substantially parallel conductive walls being substantially perpendicular to the first plurality of substantially parallel conductive walls such that the leadframe forms a substantially rectangular grid; each wall of the second plurality of substantially parallel conductive walls comprises a double wall having a first sub-wall and a second sub-wall substantially parallel to the first sub-wall; each of the plurality of semiconductor dies is disposed on the temporary substrate such each of the plurality of semiconductor dies is positioned between two adjacent ones of the first plurality of substantially parallel conductive walls and two adjacent ones of the second plurality of substantially parallel conductive walls; and the assembly is singulated such that each FO-WLCSP comprises a portion of a first sub-wall of a corresponding one of the first plurality of substantially parallel conductive walls, a portion of a second sub-wall of a different corresponding one of the first plurality of substantially parallel conductive walls, a portion of a first sub-wall of a corresponding one of the second plurality of substantially parallel conductive walls, and a portion of a second sub-wall of a different corresponding one of the second plurality of substantially parallel conductive walls.

In some embodiments, each of the first plurality of substantially parallel conductive walls comprises a U-shaped wall having a connecting portion joining edges of the first sub-wall and edges of the second sub-wall; and each of the second plurality of substantially parallel conductive walls comprises a U-shaped wall having a connecting portion joining edges of the first sub-wall and edges of the second sub-wall.

In some embodiments, the connecting portions of each of the first plurality of substantially parallel conductive walls join the edges of the first sub-wall and the edges of the second sub-wall that are proximal to the temporary substrate; and the connecting portions of each of the second plurality of substantially parallel conductive walls join the edges of the first sub-wall and the edges of the second sub-wall that are proximal to the temporary substrate.

In some embodiments, the connecting portions of each of the first plurality of substantially parallel conductive walls join the edges of the first sub-wall and the edges of the second sub-wall that are distal to the temporary substrate; and the connecting portions of each of the second plurality of substantially parallel conductive walls join the edges of the first sub-wall and the edges of the second sub-wall that are distal to the temporary substrate.

In some embodiments, a plurality of holes is defined in the first sub-wall and/or the second sub-wall of each of the first plurality of substantially parallel conductive walls to enable the molding compound to flow between the first sub-wall and the second sub-wall of each of the first plurality of substantially parallel conductive walls; and a plurality of holes is defined in the first sub-wall and/or the second sub-wall of each of the second plurality of substantially parallel conductive walls to enable the molding compound to flow between the first sub-wall and the second sub-wall of each of the second plurality of substantially parallel conductive walls.

In some embodiments, the plurality of substantially parallel conductive walls comprise copper.

In some embodiments, the molding compound comprises epoxy.

In some embodiments, the temporary substrate comprises wafer tape.

In some embodiments, the method further comprises, prior to singulating the assembly, back-grinding a portion of the molding compound and portions of each of the plurality of semiconductor dies opposite the active layers to expose edges of the plurality of substantially parallel conductive walls.

In some embodiments, the method further comprises disposing a metallization layer in electrical contact with the exposed edges of the plurality of substantially parallel conductive walls.

In accordance with various embodiments of the present disclosure, a fan-out wafer-level chip scale package is provided that comprises a semiconductor die having a top side with an active layer, an opposing bottom side, and four peripheral sides; a molding compound surrounding the peripheral sides of the semiconductor die; a redistribution layer at least partially embedded in a dielectric layer and providing a plurality of electrical connections to the semiconductor die; a plurality of solder balls on the redistribution layer, each of the plurality of solder balls providing an electrical connection to a corresponding connection point of the semiconductor die; and a first conductive wall embedded in the molding compound adjacent and substantially parallel to a first one of the peripheral sides of the semiconductor die, the first conductive wall having a top edge in electrical contact with the redistribution layer.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

The description of the illustrative embodiments may be read in conjunction with the accompanying figures. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise. Embodiments incorporating teachings of the present disclosure are shown and described with respect to the figures presented herein, in which:

FIGS. 1-6 are sectional views illustrating example steps of constructing an example FO-WLCSP assembly, in accordance with some embodiments of the present disclosure;

FIG. 7 is a sectional view of an example FO-WLCSP singulated from the assembly of FIGS. 1-6, in accordance with some embodiments of the present disclosure;

FIGS. 8-11 illustrate example leadframes used to construct example FO-WLCSP assemblies, in accordance with some alternative embodiments of the present disclosure;

FIG. 12A is a sectional view illustrating a step of constructing an example FO-WLCSP assembly, in accordance with some alternative embodiments of the present disclosure; and

FIG. 12B is a side view of a portion of an example leadframe used to construct an example FO-WLCSP assembly, in accordance with some alternative embodiments of the present disclosure.

### DETAILED DESCRIPTION OF THE INVENTION

Some embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

Various embodiments of the present disclosure overcome the above technical challenges and difficulties and provide various technical improvements and advantages based on, for example, but not limited to, providing FO-WLCSP packages and methods of constructing FO-WLCSP packages such that each FO-WLCSP package comprises a conductive bar or wall on one, two, or four sides of the die. Such conductive walls provide cost effective connections between the ball grid array and a back side metallization as well as electromagnetic force (EMF) protection.

Embodiments of the present disclosure involve securing an array of elongated conductive bars to an adhesive surface (e.g., wafer tape) commonly used for FO-WLCSP package construction, such that the conductive bars are positioned between the dies during molding and, when the completed FO-WLCSP packages are singulated, the bars are integrated with each FO-WLCSP package (on either one, two, or four sides of the die, as described below).

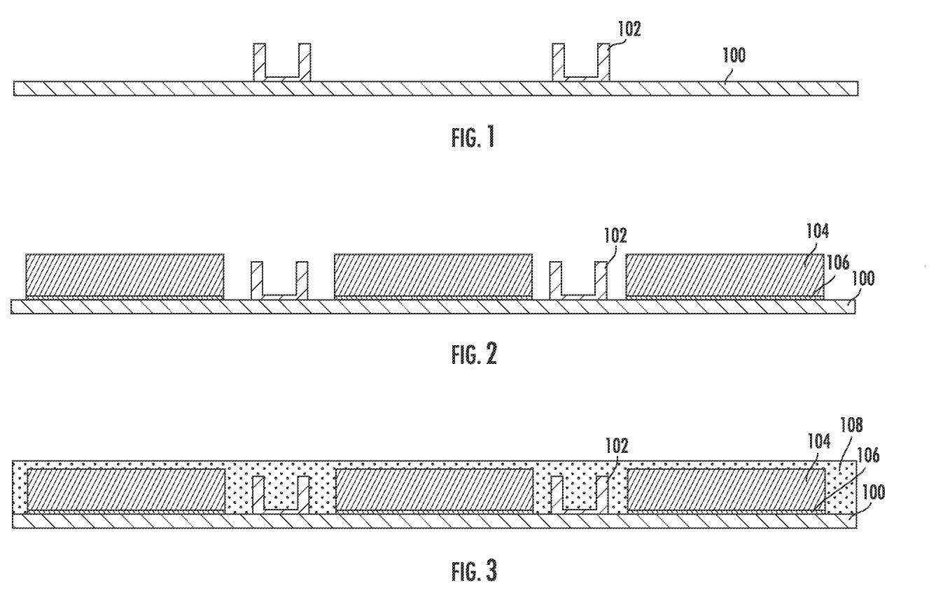

Referring now to the figures, FIGS. 1-6 are sectional views illustrating example steps of constructing an example FO-WLCSP assembly in accordance with some embodiments of the present disclosure. As illustrated in FIG. 1, a leadframe 102 comprising a plurality of conductive bars (two are illustrated in FIGS. 1-6) is secured to a temporary substrate 100. In various embodiments, any suitable temporary substrate may be used, for example wafer tape. In various embodiments, the conductive bars may be constructed of any suitable conductive material, for example copper.

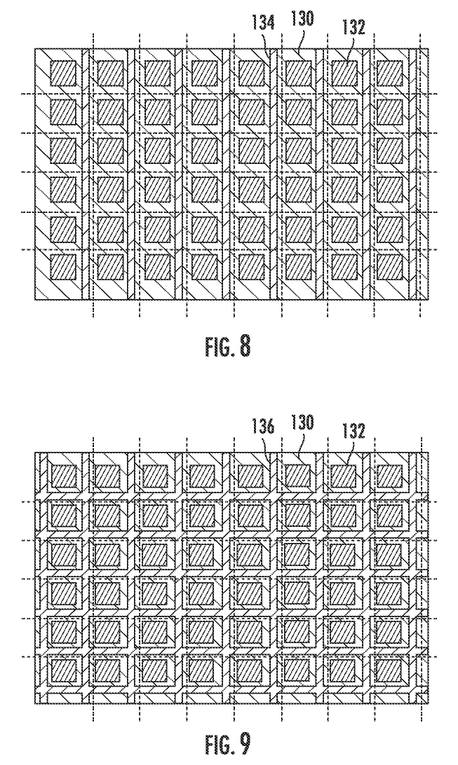

In various embodiments, as described further below, the leadframe 102 may comprise a plurality of substantially parallel single conductive bars (as illustrated in FIG. 8), a plurality of substantially parallel double conductive bars (as illustrated in FIGS. 1-6 and 10), a substantially rectangular grid of single conductive bars (as illustrated in FIG. 9), or a substantially rectangular grid of substantially parallel double conductive bars (as illustrated in FIG. 11).

As illustrated in FIG. 2, a plurality of semiconductor dies 104 (three are illustrated in FIGS. 1-6) are disposed on the temporary substrate 100 between the conductive bars 102. In various embodiments, the semiconductor dies 104 are disposed with their active region or layer 106 against the temporary substrate 100. The specific positioning of the semiconductor dies in relation to the conductive bars may vary depending on the specific arrangement desired in the final FO-WLCSP, as described further below.

As illustrated in FIG. 3, a molding compound 108 is applied over the semiconductor dies 104 and conductive bars 102. In various embodiments, any suitable molding compound may be used, for example epoxy. Once the molding compound has cured, the temporary substrate 100 is removed and the assembly is flipped over.

As illustrated in FIG. 4, after the temporary substrate 100 has been removed and the assembly has been flipped over, a plurality of redistribution layers 112 (disposed in a dielectric material 110) are disposed on the active layer 106 of corresponding ones of the plurality of semiconductor dies 104. Each of the redistribution layers 112 provide a plurality of electrical connections to a corresponding one of the semiconductor dies 104, such that there is improved spacing of electrical connections of the FO-WLCSP. In various embodiments, any suitable arrangement of the redistribution layers may be used to provide the desired spacing of electrical connections. As illustrated in FIG. 4, some of the redistribution layer connections may be made to the conductive bars 102.

As illustrated in FIG. 5, some of the molding compound 108 and some of the inactive portion of the semiconductor dies 104 may be ground away to thin the FO-WLCSP packages and to expose the edges of the conductive bars 102. This step is often referred to as back grinding.

As illustrated in FIG. 6, a plurality of solder balls 114 are attached to the redistribution layers 112 to form a ball grid array. The solder balls 114 provide an effective connection point for electrical connections between the FO-WLCSP and external circuitry. As also illustrated in FIG. 6, a metallic layer 116 (for example, copper) is optionally applied to the side of the assembly which was ground away in FIG. 5. This step is often referred to a back side metallization. In various embodiments, the metallic layer 116 is electrically connected to the exposed edges of the conductive bars 102.

In various embodiments, the assembly is now complete and may be singulated, such as along the dashed lines in FIG. 6, into a plurality of individual FO-WLCSP packages. In various embodiments, any suitable singulation method may be used.

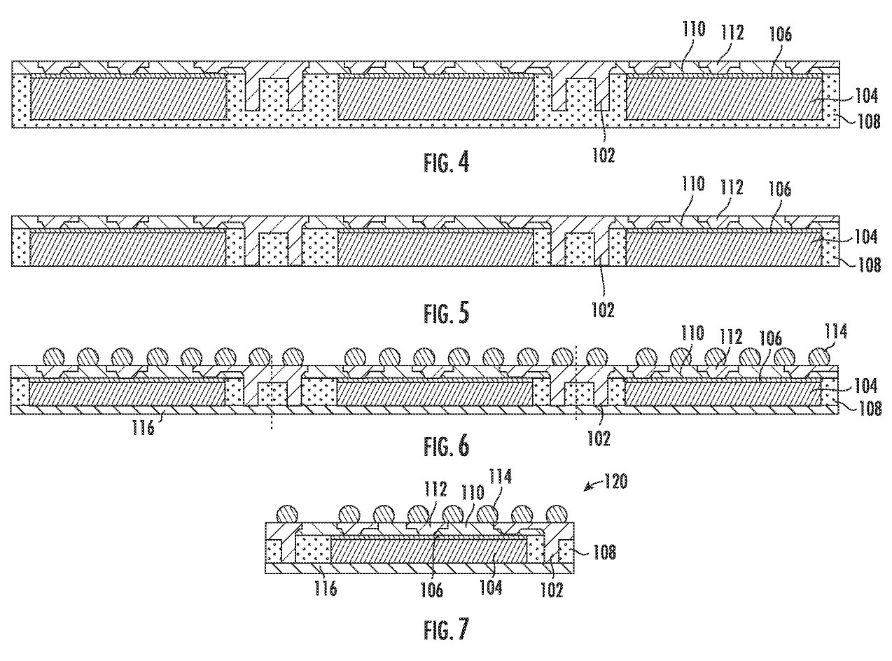

FIG. 7 illustrates a singulated FO-WLCSP package 120 comprising a semiconductor die 104 having an active layer 106 and surrounded on its peripheral sides by a molding compound 108, a redistribution layer 112 at least partially embedded in a dielectric layer 110 and providing a plurality of electrical connections to the semiconductor die 104, a plurality of solder balls 114 on the redistribution layer 112 providing an electrical connection to a corresponding connection point of the semiconductor die 104, a metallic layer 116 on a side of the package 120 opposite the redistribution layer 112, and conductive bars 102 embedded in the molding compound 108 on opposing sides of the semiconductor die 104.

In various embodiments, as illustrated in FIG. 8, the leadframe may comprise a plurality of substantially parallel single conductive bars 134 (shown affixed to a temporary substrate 130). In the embodiment of FIG. 8, the semiconductor dies 132 are arranged in subgroups (in FIG. 8 each column is a subgroup) and the semiconductor dies 132 in each subgroup are positioned with a same side adjacent to a corresponding conductive bar 134. In this regard, when singulated as indicated by the dashed lines in FIG. 8, each FO-WLCSP package will have one conductive bar on one side of its semiconductor die.

In various embodiments, as illustrated in FIG. 9, the leadframe may comprise a substantially rectangular grid of single conductive bars 136 (shown affixed to a temporary substrate 130). In the embodiment of FIG. 9, the semiconductor dies 132 are disposed in the spaces in the grid. In this regard, when singulated as indicated by the dashed lines in FIG. 9, each FO-WLCSP package will have one conductive bar on one side of its semiconductor die and one conductive bar on an adjacent side of its semiconductor die.

In various embodiments, as illustrated in FIG. 10, the leadframe may comprise a plurality of substantially parallel double conductive bars 138 (shown affixed to a temporary substrate 130). In the embodiment of FIG. 10, the semiconductor dies 132 are arranged in subgroups (in FIG. 10 each column is a subgroup) and the semiconductor dies 132 in each subgroup are positioned between two adjacent double conductive bars 138. In this regard, when singulated as indicated by the dashed lines in FIG. 10, each FO-WLCSP package will have one conductive bar on one side of its semiconductor die and one conductive bar on an opposite side of its semiconductor die.

In various embodiments, as illustrated in FIG. 11, the leadframe may comprise a substantially rectangular grid of double conductive bars 140 (shown affixed to a temporary substrate 130). In the embodiment of FIG. 11, the semiconductor dies 132 are disposed in the spaces in the grid. In this regard, when singulated as indicated by the dashed lines in FIG. 11, each FO-WLCSP package will have conductive bars on all sides of its semiconductor die.

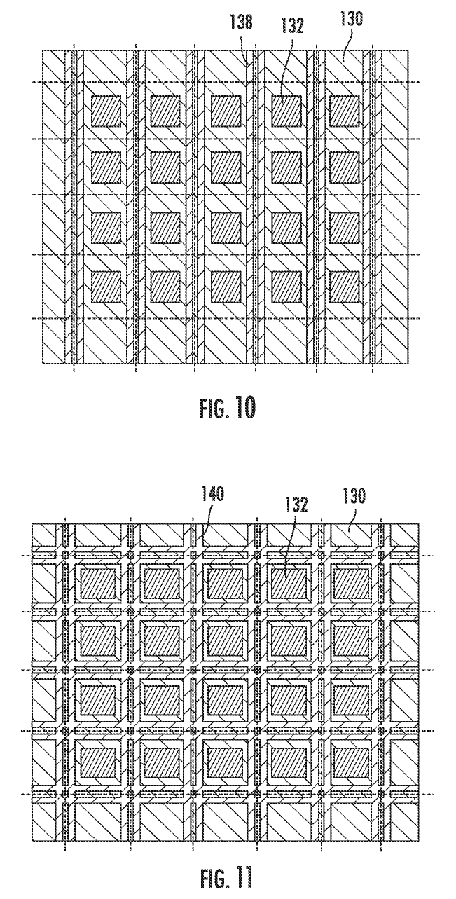

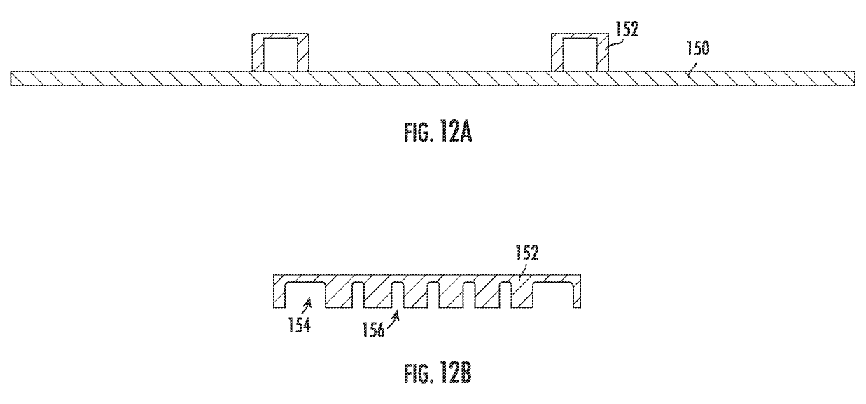

As described above, various embodiments may use a leadframe that comprises a double conductive bars, either substantially parallel (as illustrated in FIGS. 1-6 and 10) or in a substantially rectangular grid (as illustrated in FIG. 11). In various embodiments, the double conductive bars may be disposed on the temporary substrate as two separate bars or, for example, as a U-shaped wall having first and second sub-walls projecting out from the temporary substrate and a connecting portion joining an edge of the first sub-wall and an edge of the second sub-wall. In the embodiments of FIGS. 1-6, the connecting portion is in contact with the temporary substrate 100 and joins the proximal edges of the first and second sub-wall (this may be thought of as a right side up U). In an alternative embodiment illustrated in FIG. 12A, the connecting portion of the U-shaped conductive wall 152 is not in contact with the temporary substrate 150 and joins the distal edges of the first and second sub-wall (this may be thought of as an upside-down U). In the embodiment of FIG. 12A, the distal connecting portion would likely block the molding compound from flowing into the space between the first and second sub-walls. To enable the molding compound to flow into the space between the first and second sub-walls in such an embodiment, the first and/or second sub-wall may have one or more holes defined therein. FIG. 12B illustrates a side view of a portion of the upside-down U-shaped conductive wall 152 with larger holes 154 and smaller holes 156. In various embodiments, the larger holes 154 may coincide with intersections at which two perpendicular upside-down U-shaped conductive walls meet and the smaller holes 156 may be placed along the walls between such intersections. Although not illustrated, the connecting wall in upside down U-shaped double conductive bars may have a plurality of holes defined therein to enable the molding compound to flow into the space between the first and second sub-walls (instead of or in addition to the holes in one or both sub-walls).

Various embodiments of the disclosure provide a simple and effective way of providing EMF protection and backside connection in a FO-WLCSP package. The embodiment of FIG. 11, especially with backside metallization, may provide particularly effective EMF protection.

### Conclusion

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components may be used in conjunction with the system. Therefore, it is to be understood that the disclosures are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the disclosure(s) set out in any claims that may issue from this disclosure.

While this detailed description has set forth some embodiments of the present disclosure, the appended claims cover other embodiments of the present disclosure which differ from the described embodiments according to various modifications and improvements. For example, the appended claims can cover any form of FO-WLCSP.

Within the appended claims, unless the specific term “means for” or “step for” is used within a given claim, it is not intended that the claim be interpreted under 35 U.S.C. 112, paragraph 6.

What is claimed is:

1. A method of manufacturing a semiconductor device, the method comprising:
(i) constructing an assembly, wherein constructing the assembly comprises:
(a) disposing a leadframe on a temporary substrate, the leadframe comprising at least a plurality of substantially parallel conductive walls;
(b) disposing a plurality of semiconductor dies on the temporary substrate, each of the plurality of semiconductor dies disposed with its active layer against the temporary substrate, the plurality of semiconductor dies comprising a plurality of subgroups of semiconductor dies, each subgroup of semiconductor dies is disposed on the temporary substrate such that a same side of each of the plurality of semiconductor dies in each subgroup of semiconductor dies is adjacent a corresponding one of the plurality of substantially parallel conductive walls;
(c) enclosing the leadframe and the plurality of semiconductor dies in a molding compound;
(d) removing the temporary substrate;
(e) disposing a plurality of redistribution layers on the active layer of corresponding ones of the plurality of semiconductor dies such that each of the plurality of redistribution layers provides a plurality of electrical connections to a corresponding one of the plurality of semiconductor dies, each of the plurality of redistribution layers at least partially embedded in a dielectric layer; and
(f) disposing a plurality of solder balls on each of the plurality of redistribution layers, each of the plurality of solder balls providing an electrical connection to a corresponding connection point of a corresponding one of the plurality of semiconductor dies; and
(ii) singulating the assembly into a plurality of fan-out wafer-level chip scale packages (FO-WLCSP), each FO-WLCSP comprising a corresponding one of the plurality of semiconductor dies, a corresponding one of the plurality of redistribution layers, corresponding ones of the plurality of solder balls, and a portion of a corresponding one of the plurality of substantially parallel conductive walls.

2. The method of claim 1, wherein the plurality of substantially parallel conductive walls is a first plurality of substantially parallel conductive walls;
wherein the leadframe comprises a second plurality of substantially parallel conductive walls, each wall of the second plurality of substantially parallel conductive walls being substantially perpendicular to the first plurality of substantially parallel conductive walls such that the leadframe forms a substantially rectangular grid;
wherein each of the plurality of semiconductor dies is disposed on the temporary substrate such that two adjacent sides of each of the plurality of semiconductor dies are adjacent, respectively, a portion of a corresponding one of the first plurality of substantially parallel conductive walls and a portion of a corresponding one of the second plurality of substantially parallel conductive walls; and
wherein the assembly is singulated such that each FO-WLCSP comprises a corresponding portion of the corresponding one of the first plurality of substantially parallel conductive walls and a corresponding portion of the corresponding one of the second plurality of substantially parallel conductive walls.

3. The method of claim 2, wherein each of the first plurality of substantially parallel conductive walls comprises a double wall having a first sub-wall and a second sub-wall substantially parallel to the first sub-wall; and
wherein the assembly is singulated such that each FO-WLCSP comprises a portion of a first sub-wall of a corresponding one of the plurality of substantially parallel conductive walls on one side of each semiconductor die and a portion of a second sub-wall of a different corresponding one of the plurality of substantially parallel conductive walls on an opposite side of each semiconductor die.

4. The method of claim 1, wherein the plurality of substantially parallel conductive walls is a first plurality of substantially parallel conductive walls;
wherein each of the first plurality of substantially parallel conductive walls comprises a double wall having a first sub-wall and a second sub-wall substantially parallel to the first sub-wall;
wherein the leadframe comprises a second plurality of substantially parallel conductive walls, each wall of the second plurality of substantially parallel conductive walls being substantially perpendicular to the first plurality of substantially parallel conductive walls such that the leadframe forms a substantially rectangular grid;
wherein each wall of the second plurality of substantially parallel conductive walls comprises a double wall having a first sub-wall and a second sub-wall substantially parallel to the first sub-wall;
wherein each of the plurality of semiconductor dies is disposed on the temporary substrate such each of the plurality of semiconductor dies is positioned between two adjacent ones of the first plurality of substantially parallel conductive walls and two adjacent ones of the second plurality of substantially parallel conductive walls; and
wherein the assembly is singulated such that each FO-WLCSP comprises a portion of a first sub-wall of a corresponding one of the first plurality of substantially parallel conductive walls, a portion of a second sub-wall of a different corresponding one of the first plurality of substantially parallel conductive walls, a portion of a first sub-wall of a corresponding one of the second plurality of substantially parallel conductive walls, and a portion of a second sub-wall of a different corresponding one of the second plurality of substantially parallel conductive walls.

5. The method of claim 4, wherein each of the first plurality of substantially parallel conductive walls comprises a U-shaped wall having a connecting portion joining edges of the first sub-wall and edges of the second sub-wall; and
wherein each of the second plurality of substantially parallel conductive walls comprises a U-shaped wall having a connecting portion joining edges of the first sub-wall and edges of the second sub-wall.

6. The method of claim 5, wherein the connecting portions of each of the first plurality of substantially parallel conductive walls join the edges of the first sub-wall and the edges of the second sub-wall that are proximal to the temporary substrate; and
wherein the connecting portions of each of the second plurality of substantially parallel conductive walls join the edges of the first sub-wall and the edges of the second sub-wall that are proximal to the temporary substrate.

7. The method of claim 5, wherein the connecting portions of each of the first plurality of substantially parallel conductive walls join the edges of the first sub-wall and the edges of the second sub-wall that are distal to the temporary substrate; and
wherein the connecting portions of each of the second plurality of substantially parallel conductive walls join the edges of the first sub-wall and the edges of the second sub-wall that are distal to the temporary substrate.

8. The method of claim 7, wherein a plurality of holes is defined in the first sub-wall and/or the second sub-wall of each of the first plurality of substantially parallel conductive walls to enable the molding compound to flow between the first sub-wall and the second sub-wall of each of the first plurality of substantially parallel conductive walls; and
wherein a plurality of holes is defined in the first sub-wall and/or the second sub-wall of each of the second plurality of substantially parallel conductive walls to enable the molding compound to flow between the first sub-wall and the second sub-wall of each of the second plurality of substantially parallel conductive walls.

9. The method of claim 1, wherein the plurality of substantially parallel conductive walls comprise copper.

10. The method of claim 1, wherein the molding compound comprises epoxy.

11. The method of claim 1, wherein the temporary substrate comprises wafer tape.

12. The method of claim 1, further comprising, prior to singulating the assembly, back-grinding a portion of the molding compound and portions of each of the plurality of semiconductor dies opposite the active layers to expose edges of the plurality of substantially parallel conductive walls.

13. The method of claim 12, further comprising disposing a metallization layer in electrical contact with the exposed edges of the plurality of substantially parallel conductive walls.

14. A fan-out wafer-level chip scale package (FO-WLCSP) comprising:
a semiconductor die having a top side with an active layer, an opposing bottom side, and four peripheral sides;
a molding compound surrounding the peripheral sides of the semiconductor die;
a redistribution layer at least partially embedded in a dielectric layer and providing a plurality of electrical connections to the semiconductor die;
a plurality of solder balls on the redistribution layer, each of the plurality of solder balls providing an electrical connection to a corresponding connection point of the semiconductor die; and
a first conductive wall embedded in the molding compound adjacent and substantially parallel to a first one of the peripheral sides of the semiconductor die, the first conductive wall having a top edge in electrical contact with the redistribution layer.

15. The FO-WLCSP of claim 14, further comprising:
a second conductive wall embedded in the molding compound adjacent and substantially parallel to a second one of the peripheral sides of the semiconductor die, the second conductive wall having a top edge in electrical contact with the redistribution layer;
wherein the second one of the peripheral sides of the semiconductor die is adjacent to the first one of the peripheral sides of the semiconductor die.

16. The FO-WLCSP of claim 14, further comprising:
a second conductive wall embedded in the molding compound adjacent and substantially parallel to a second one of the peripheral sides of the semiconductor die, the second conductive wall having a top edge in electrical contact with the redistribution layer;
wherein the second one of the peripheral sides of the semiconductor die is opposite the first one of the peripheral sides of the semiconductor die.

17. The FO-WLCSP of claim 14, further comprising:
a second conductive wall embedded in the molding compound adjacent and substantially parallel to a second one of the peripheral sides of the semiconductor die, the second conductive wall having a top edge in electrical contact with the redistribution layer;
a third conductive wall embedded in the molding compound adjacent and substantially parallel to a third one of the peripheral sides of the semiconductor die, the third conductive wall having a top edge in electrical contact with the redistribution layer; and
a fourth conductive wall embedded in the molding compound adjacent and substantially parallel to a fourth one of the peripheral sides of the semiconductor die, the fourth conductive wall having a top edge in electrical contact with the redistribution layer.

18. The FO-WLCSP of claim 17, further comprising a metallization layer in electrical contact with a bottom edge of each of the first, second, third, and fourth conductive walls.

19. The FO-WLCSP of claim 17, wherein each of the first, second, third, and fourth conductive walls comprise copper.

20. The FO-WLCSP of claim 14, wherein the molding compound comprises epoxy.
